(19) United States
(12) Patent Application Publication
(10) Pub. No.: US 2025/0079301 A1
(43) Pub. Date: Mar. 6, 2025

(54) METHOD AND DEVICE FOR DISTRIBUTED TRANSFORMER ON INTEGRATED CIRCUIT CHIP

(71) Applicant: Danger Devices Inc., San Jose, CA (US)

(72) Inventors: Nicholas SUTARDJA, San Jose, CA (US); Sehat SUTARDJA, San Jose, CA (US)

(21) Appl. No.: 18/460,467

(22) Filed: Sep. 1, 2023

(51) Int. Cl. H01L 23/522; H01L 27/01

(52) U.S. Cl. CPC H01L 23/5227; H10D 86/85

(57) ABSTRACT

The present invention provides a transformer device. In an example, the transformer device has a semiconductor substrate member comprising a first surface and a second surface. In an example, the device has a metal material having a thickness and configured spatially in a pattern to form a distributed transformer device. The pattern has a plurality of primary tracks numbered from 2 to J, where J is an integer from two to forty, and a plurality of secondary tracks numbered from 2 to K, where K is an integer from two to forty. In an example, the plurality of primary tracks and the plurality of secondary tracks are configured collectively to form an electromagnetic field from the plurality of primary tracks to produce a magnetic flux to induce a varying current coupled to the plurality of secondary tracks.

### COPYRIGHT NOTICE

A portion of the disclosure of this patent document contains material to which a claim for copyright is made. The copyright owner has no objection to the facsimile reproduction by anyone of the patent document or the patent disclosure, as it appears in the Patent and Trademark Office patent file or records, but reserves all other copyright rights whatsoever.

### CROSS REFERENCE TO RELATED APPLICATIONS

N/A

### BACKGROUND OF INVENTION

A transformer has been an important component in many electrical and electronic systems. The transformer is a passive device that transfers electrical energy between two or more circuits through electromagnetic induction. Transformers have been widely used in various applications, including power transmission and distribution, electronic devices, and communication systems.

Historically, the concept of the transformer was first introduced by Michael Faraday, who was an early pioneer of electricity and magnetics, in the early 1830s. However, it was not until the late 1800s that practical transformer designs were developed. Pioneering work of William Stanley, Nikola Tesla, and Lucien Gaulard led to the development of efficient transformers suitable for power transmission.

In the context of integrated circuits (ICs), transformers have been primarily used for coupling signals between different circuits, especially in radio frequency (RF), millimeter wave (mmWave), power supply regulation, and high-speed analog and digital applications. Transformers designed for RF or mm Wave purposes are typical used for power transfer, impedance matching, coupling, and frequency transformation in RF circuits. RF transformers are commonly found in wireless communication systems, such as transceivers, RF amplifiers, and antenna systems. Transformers are commonly found in switching power supplies, motor drives, and high-speed digital interfaces. Transformers have also played a crucial role in communication systems, enabling signal transmission and isolation.

IC transformers have been predominantly and widely made with two windings: one for the primary turn(s) and another for the secondary turns(s). Each winding has been composed as one or multiple turns, implemented through an offset on the same metal layer or realized by two separate windings on different metal layers. Three winding IC transformers have been shown as well to improve coupling and efficiency, where two of the windings surround the remaining winding. The two windings are connected together at the endpoints, ultimately reducing the structure again to a single primary winding and a single secondary winding transformer.

While transformers offer advantages, they also have drawbacks. Such drawbacks include size and weight, costs, limited frequency range, and power losses, including difficulty to integrated in miniaturized ICs. Specifically, transformers in ICs suffer from increased resistance losses compared to their counterparts when realized with discrete components or physical wire windings. Despite these drawbacks, IC transformers remain indispensable in various electrical and electronic systems, playing a vital role in power transmission, signal coupling, and isolation. Advancements in transformer technology to address these limitations and improve their overall performance are desired.

### SUMMARY OF INVENTION

According to the present invention, techniques related generally to integrated circuits are provided. In particular, the present invention provides a distributed transformer device and method for communication techniques. Merely by way of example, the invention can be applied to a variety of applications, including RF circuits and designs, mm Wave circuits, power supply regulation and conversion, digital and analog amplifiers and oscillator circuits, communication circuits, and others.

In an example, the present invention provides a transformer device. In an example, the transformer device has a semiconductor substrate member comprising a first surface and a second surface. In an example, the semiconductor substrate can be a silicon wafer, a silicon on insulator wafer, a compound semiconductor material, such as any II/VI or III/V material, among others. In an example, the device has an insulting material overlying the second surface. In an example, a plurality of contact regions are configured within the insulating material. In an example, the device has a metal material having a thickness and configured spatially in a pattern to form a distributed transformer device. The pattern has a plurality of primary tracks numbered from 2 to J, where J is an integer from two to forty, and a plurality of secondary tracks numbered from 2 to K, where K is an integer from two to forty. In other examples, the number of tracks can be higher. In an example, the plurality of primary tracks and the plurality of secondary tracks are configured collectively to form an electromagnetic field from the plurality of primary tracks to produce a magnetic flux to induce a varying current coupled to the plurality of secondary tracks.

In an example, the present invention provides an alternative transformer device. The device has a semiconductor substrate member comprising a first surface and a second surface. In an example, the device has a plurality of CMOS cells configured overlying a first portion of the second surface. In an example, an insulting material is overlying a second portion of the second surface. In an example, a plurality of contact regions configured within the insulating material such that each of the contact regions comprises a via structure. In an example, the device has a metal material having a thickness and configured spatially in a pattern to form a transformer device. In an example, the pattern has a plurality of primary tracks numbered from 2 to J, where J is an integer from two to forty. Each of the primary tracks has a first end point and a second end point, and a length defined between the first end point the second end point. In an example, the pattern has a plurality of secondary tracks numbered from 2 to K, where K is an integer from two to forty. In other examples, the number of tracks can be higher. Each of the secondary tracks has a first end point and a second end point, and a length defined between the first end point and the second end point. In an example, the plurality of primary tracks and the plurality of secondary tracks are configured collectively to form an electromagnetic field from the plurality of primary tracks to produce a magnetic flux to induce a varying current coupled to the plurality of secondary tracks.

Depending upon the example, the present invention can achieve one or more of these benefits and/or advantages. In an example, the present invention provides a novel transformer design configured for use with semiconductor integrated circuits in a compact and spatially efficient system and related methods. In an example, the transformer device and methods can be configured with complementary metal oxide semiconductor (“CMOS”) circuits, and others. In an example, the present invention offers advantages of generating an efficient transformer for manufacture and scalability. These and other benefits and/or advantages are achievable with the present device and related methods. Further details of these benefits and/or advantages can be found throughout the present specification and more particularly below.

A further understanding of the nature and advantages of the Invention may be realized by reference to the latter portions of the specification and attached drawings.

### BRIEF DESCRIPTION OF THE DRAWINGS

In order to more fully understand the present invention, reference is made to the accompanying drawings. Understanding that these drawings are not to be considered limitations in the scope of the invention, the presently described embodiments and the presently understood best mode of the invention are described with additional detail through use of the accompanying drawings in which:

FIG. 1 is a simplified diagram of a generalized distributed transformer schematic diagram according to an example of the present invention.

FIG. 2 is a simplified illustration of a schematic diagram of a six track distributed transformer device with two primary tracks and four secondary tracks with two segments each according to an example of the present invention.

FIG. 3 is a simplified top-view diagram of a layout for the six track distributed transformer device according to an example of the present invention.

FIG. 4 is a simplified top-view layout of a six track distributed transformer device according to an alternative example.

FIG. 5 is a simplified diagram of a six track distributed transformer with two primary tracks, and four secondary tracks with four segments for each secondary track according to an example of the present invention.

FIG. 6 is a simplified diagram of a top view layout of six track distributed transformer device according to an alternative example of the present invention.

FIG. 7 is a simplified top-view diagram of a layout of a six track distributed transformer device according to an alternative example of the present invention.

FIG. 8 is a simplified diagram of a six track distributed transformer device according to an alternative example of the present invention.

FIG. 9 is a simplified top view diagram of a layout for a six track distributed transformer device according to an example of the present invention.

FIG. 10 is simplified side-view diagram illustrating a cross-section of a portion of various distributed transformer devices according to an example of the present invention.

FIG. 11 is a simplified cross-sectional view of various tracks for transformer devices according to an example of the present invention.

FIG. 12 is a simplified diagram of an integrated CMOS device coupled to a distributed transformer device according to an example of the present invention.

FIG. 13 is a simplified diagram of a contact structure according to an example of the present invention.

### DETAILED DESCRIPTION OF THE EXAMPLES

The present invention provides a distributed transformer device and a method for integrated circuits. In particular, the present techniques include a distributed transformer device and a method for communications. Merely by way of example, the invention can be applied to a variety of applications, including RF circuits and designs, digital and analog circuits, communications, and others.

As background, a transformer is a device used to transfer electrical energy between two or more circuits through electromagnetic induction. In the context of RF (Radio Frequency) circuits, transformers serve various functions. As an example, a transformer can be used for impedance matching. That is, one of the primary applications of transformers in RF circuits is impedance matching. Impedance matching is desirable for efficient power transfer between different stages of an RF system. Transformers can be designed to match the impedance of the input and output circuits, maximizing power transfer and minimizing signal reflections. By adjusting the turns ratio and configuration, as will be described, of the transformer, the impedance can be transformed to the desired value. Other examples include balun (Balanced-Unbalanced) conversion, voltage level shifting, isolation, coupling and coupling transformers, among others. RF transformers are typically designed to operate at higher frequencies and have specific impedance requirements to ensure proper functionality in the RF domain. Further details of the present transformer device and method can be found throughout the present specification and more particularly below.

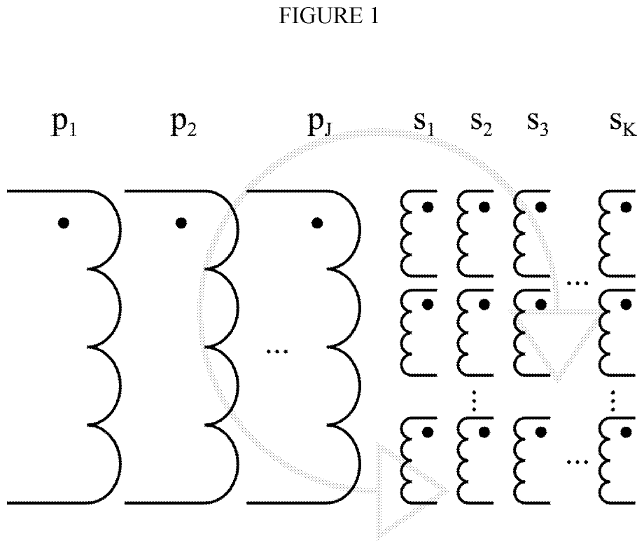

FIG. 1 is a simplified diagram of a generalized distributed transformer schematic diagram according to an example of the present invention. This diagram is merely an example. Various modifications, alternatives, and variations exist. As shown, the distributed transformer is illustrated in a generalized manner. The segments include various tracks. In an example, the segments include a plurality of primary tracks (e.g., p₁ . . . p_{J}). The segments also include a plurality of segments of the secondary tracks (e.g., s₁ . . . s_{K}). Each of the segments is electrically and spatially tightly coupled (e.g., maintain overall shape) to every other segment with varying coupling factors depending on spatial proximity of segments. In an example, each of the secondary tracks comprises at least a pair of segments where each segment has a pair of terminations on each end.

In an example, each of the tracks has a pair of nodes configured on each side of the tracks. Each of the nodes are coupled and/or directly connected to a device element, such as a bonding pad, a transistor element, such as a gate, drain, or source, among others. Each of the device elements are part of a larger element or component.

As used herein, the term “tightly coupled” means the plurality of tracks are in a shifted structure, as shown in an example, to form a representative shape without variations that detrimentally influence electromagnetic characteristic.

As used herein, the term “track” means a linear structure with a width, thickness, and length that is free from multiple conventional coils or windings (as used in conventional transformers) in an example, although other meanings understood by someone of ordinary skill in the art would also apply. Various examples of tracks are shown in the drawings but are not limiting.

In an example, the coupling factors include spatial shape, width, and length, and proximity of one or more tracks, among other factors. In an example, multiple tracks such as 2 . . . J primary and 2 . . . K secondary allow for tight coupling, specific control over which tracks should couple together, and layout symmetry.

In an example, each of the tracks is made of a metal or combination of metal materials. Examples of such metal material include aluminum (Al), copper (Cu), gold (Au), titanium (Ti), tungsten (W), and nickel (Ni), among others. As an example, aluminum interconnects in integrated circuits (ICs). Aluminum offers good conductivity, low resistivity, and compatibility with silicon-based processes. However, aluminum is commonly used for metal layers in older-generation ICs. More recently, copper has become increasingly popular for interconnects due to its superior electrical conductivity compared to aluminum. Copper has a lower resistance and can handle higher current densities, making it suitable for advanced ICs. Copper is preferably used for the present distributed transformer device. Other examples include gold in high-end ICs and applications requiring high-quality connections. Other materials include titanium, which is often a barrier metal in semiconductor manufacturing processes. Tungsten is employed as a contact material in semiconductor devices. Tungsten is often used in conjunction with titanium to create a TiW alloy for contact formation. Nickel can be used as a barrier metal to prevent diffusion, similar to titanium in an example. The specific choice of metal depends on the intended application, process compatibility, and performance requirements of the semiconductor device.

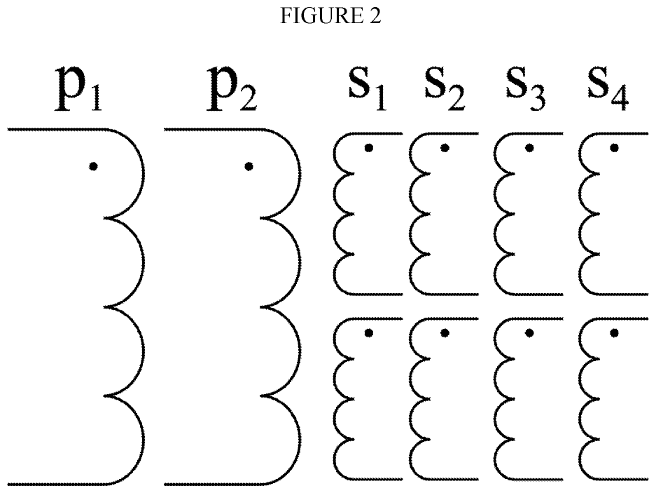

FIG. 2 is a simplified illustration of a schematic diagram of a six track distributed transformer device with two primary tracks and four secondary tracks with two segments each according to an example of the present invention. In an example as shown, the present invention provides for a six track distributed transformer with two primary tracks, and four secondary tracks with two segments for each secondary track.

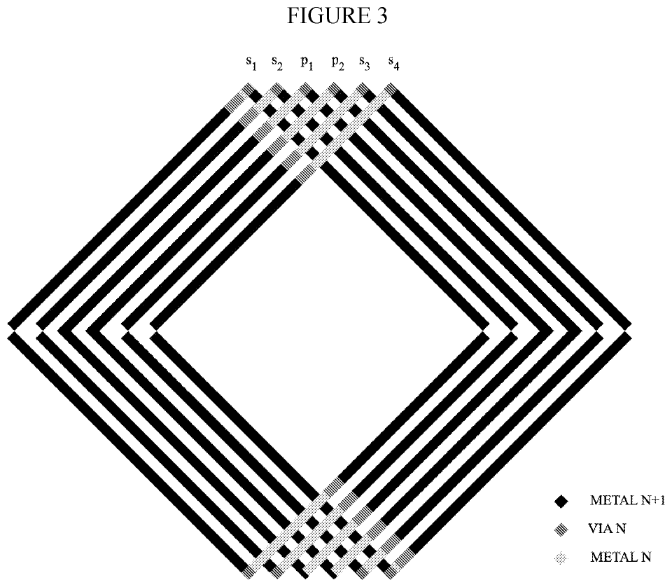

FIG. 3 is a simplified top-view diagram of a layout for the six track distributed transformer device according to an example of the present invention. As shown, the top view layout example is a schematic with a permutation of tracks in order secondary, secondary, primary, primary, secondary, secondary for a one rhombus version, e.g., single rhombus shaped. In an example, tracks can be permuted depending on which tracks should be more tightly coupled. As shown, each secondary track has an opening (e.g., open circuit) between a pair of segments. Each of the secondary tracks can include a plurality of segments, each having a first end and a second end.

In an example, the device is fabricated on a semiconductor substrate member comprising a first surface and a second surface. An insulting material is overlying the second surface. A metal material has a thickness and is configured spatially in a pattern. In an example, the metal material can have a first metal pattern in a first metal layer within a first layer region and a second metal pattern in a second metal layer within a second layer region, which is overlying the first metal layer with an insulating material in between the first metal layer and the second metal layer. As shown, a plurality of rhombus shaped tracks numbered from 4 to N, where N is an integer from 4 to 80, are configured from the pattern. The plurality of rhombus shaped tracks are configured in a shifted arrangement such that a second rhombus shaped track is placed adjacent to a first rhombus shaped track, a third rhombus shaped track is placed adjacent to the second rhombus shaped track, and the Nth rhombus shaped track is placed adjacent to an N−1 rhombus shaped track. Each pair of lateral corners opposed to each other for each rhombus shaped track is arranged along a first lateral imaginary line. See FIG. 3 corners opposed to each other along a horizontal center of the rhombus shaped track along a straight horizontal imaginary line. A first vertical corner for each rhombus shaped track is arranged along a second lateral imaginary line in parallel with the first lateral imaginary line, and a second vertical corner for each rhombus shaped track is arranged along a third lateral imaginary line in parallel to the first lateral imaginary line. See FIG. 3 lower corners of each rhombus shaped track at the bottom of the page formed along the second lateral imaginary line (straight line), and upper corners of each rhombus shaped track at the top of the page formed along the third lateral imaginary line (straight line).

In an example, the transformer device is configured from a plurality of primary tracks (e.g., P1, P2) comprising at least a first pair of the rhombus shaped tracks and a plurality of secondary tracks (e.g., S1, S2, S3, S4) comprising at least a second pair of the rhombus shaped tracks such that the plurality of primary tracks forms an electromagnetic field and resulting magnetic flex to induct a varying current coupled to one or more of the plurality of secondary tracks.

In an example, the plurality of rhombus shaped tracks are configured such that each rhombus shaped track is shifted by a gap to an adjacent rhombus shaped track. In an example, each of the plurality of rhombus shaped tracks is isolated from any other one of the plurality of rhombus shaped tracks. In an example, each of the N−1 of the plurality of rhombus shaped tracks is configured with a gap to be isolated from at least one or more of the plurality of rhombus shaped tracks.

In an example, a rhombus shape is a four-sided geometric shape that falls under the category of quadrilaterals. In an example, the rhombus shape is characterized by having all four sides of equal length, which means that it is an equilateral quadrilateral. In addition to having equal sides, a rhombus also has opposite angles that are congruent (equal) to each other. This means that if you label the angles as A, B, C, and D, with A and C being opposite angles and B and D being opposite angles, then A=C and B=D. In other examples, the rhombus shape can be replaced by other shapes and variations. In an example, other quadrilaterals can be used as a pattern. However, a rhombus is a quadrilateral with four sides of equal length and opposite angles that are congruent. It possesses diagonals that are perpendicular to each other and intersects at their center. While its sides are equal, the angles within a rhombus are not necessarily right angles. Of course, other variations can exist.

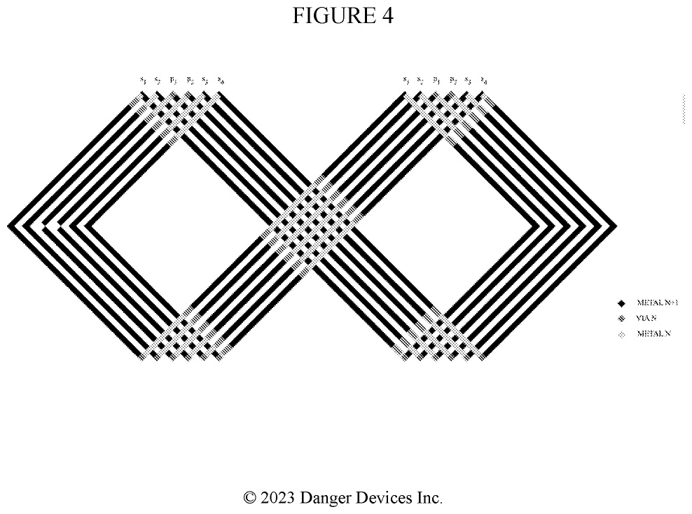

FIG. 4 is a simplified top-view layout of a six track distributed transformer device according to an alternative example. As shown, the top view layout is a schematic with a permutation of tracks in order secondary, secondary, primary, primary, secondary, secondary for a two rhombus version. As shown, each rhombus is symmetrically configured with each other, connected by opposite apex regions of each rhombus. In an example, the tracks can be permuted depending on which tracks should be more tightly coupled.

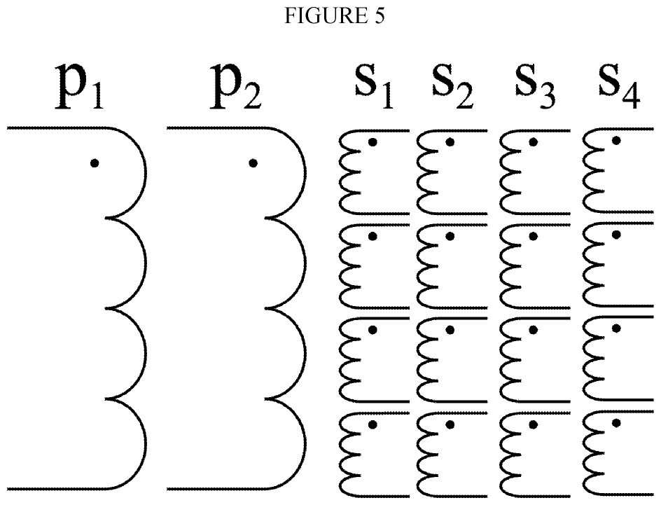

FIG. 5 is a simplified diagram of a six track distributed transformer with two primary tracks, and four secondary tracks with four segments for each secondary track according to an example of the present invention. As shown the two primary tracks include P1 and P2. The secondary tracks include S1, S2, S3, and S4. Each of the secondary tracks have four segments, as shown.

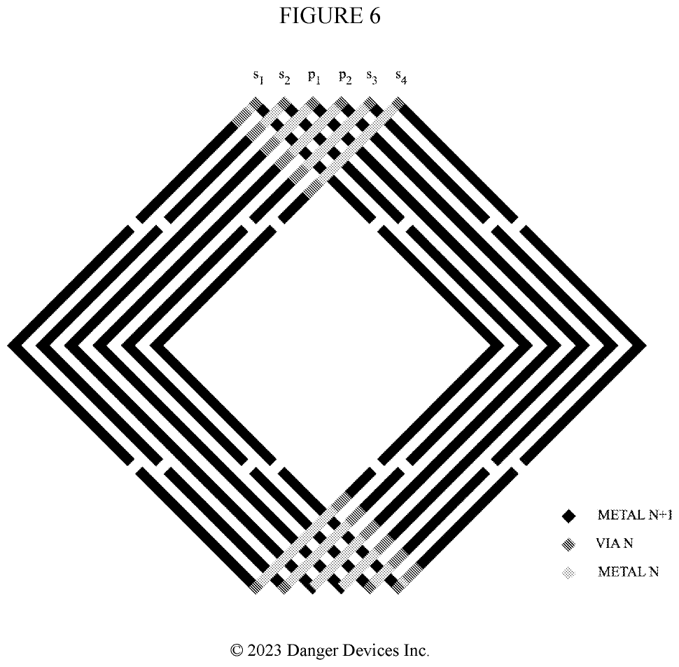

FIG. 6 is a simplified diagram of a top view layout of six track distributed transformer device according to an alternative example of the present invention. As shown, the top view layout example has a schematic with a permutation of tracks in order secondary, secondary, primary, primary, secondary, secondary for a one rhombus version. As shown, tracks can be permuted depending on which tracks should be more tightly coupled.

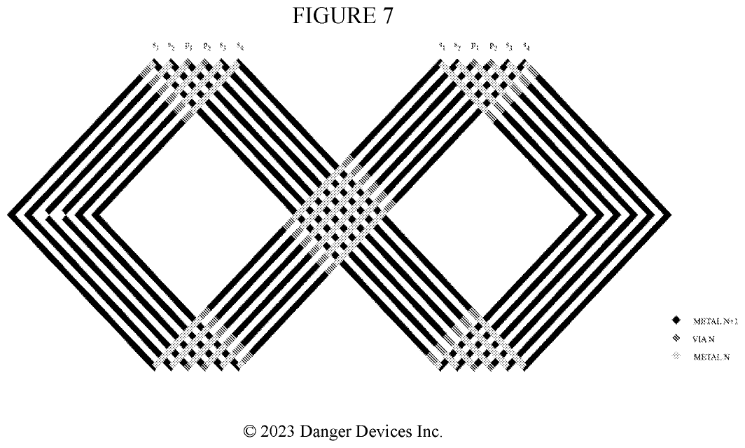

FIG. 7 is a simplified top-view diagram of a layout of a six track distributed transformer device according to an alternative example of the present invention. As shown, the top view layout example is a schematic with a permutation of tracks in order secondary, secondary, primary, primary, secondary, secondary for a two rhombus version. Each rhombus is symmetric with the other rhombus. As shown, tracks can be permuted depending on which tracks should be more tightly coupled.

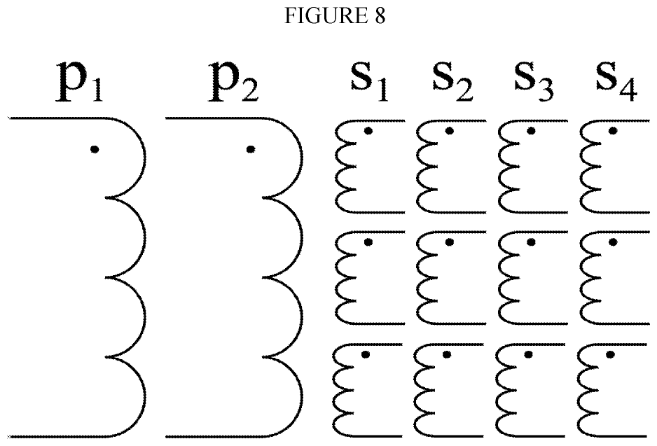

FIG. 8 is a simplified diagram of a six track distributed transformer device according to an alternative example of the present invention. As shown, the transformer device is configured as a six track distributed transformer with two primary tracks, and four secondary tracks with three segments for each secondary track.

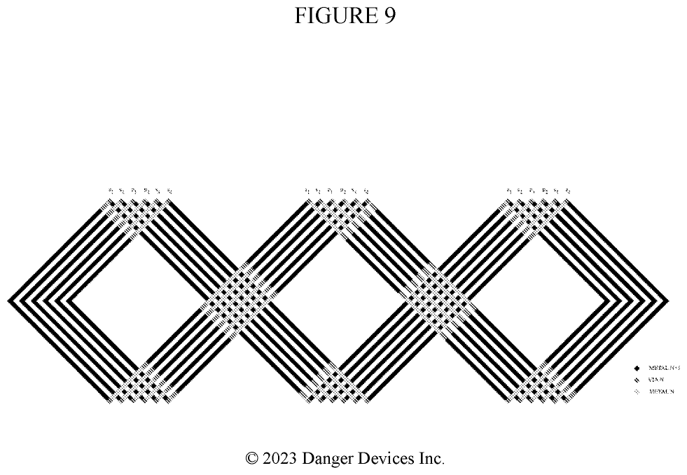

FIG. 9 is a simplified top view diagram of a layout for a six track distributed transformer device according to an example of the present invention. As shown, the top view layout example illustrates a permutation of tracks in order secondary, secondary, primary, primary, secondary, secondary for a three rhombus version. Each rhombus is symmetrically arranged with the others. As shown, the tracks can be permuted depending on which tracks should be more tightly coupled.

Further details of a side-view diagram of any of the aforementioned examples can be found throughout the present specification and more particularly below.

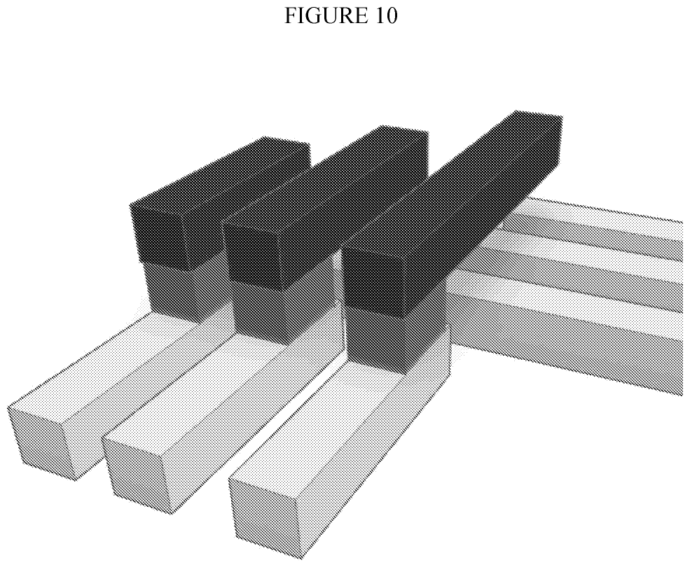

FIG. 10 is simplified side-view diagram illustrating a cross-section of a portion of various distributed transformer devices according to an example of the present invention. As shown, the diagram illustrates a plurality of tracks arranged in parallel crossing another plurality of tracks configured in parallel. As shown, the cross-section of a layout illustrates where metal tracks N are connected to metal tracks N+1 through via structures N, each of which forms an “s-like” structure. The metal tracks form crossings that allow for the distributed transformer to be realized with electrically isolated from one set of tracks to form nets by way of shifting of tracks overlying a plurality of other tracks. An isolation material (e.g., silicon dioxide, nitride, or other glass material) fills regions surrounding the metal track regions, via structures, and underlying track regions.

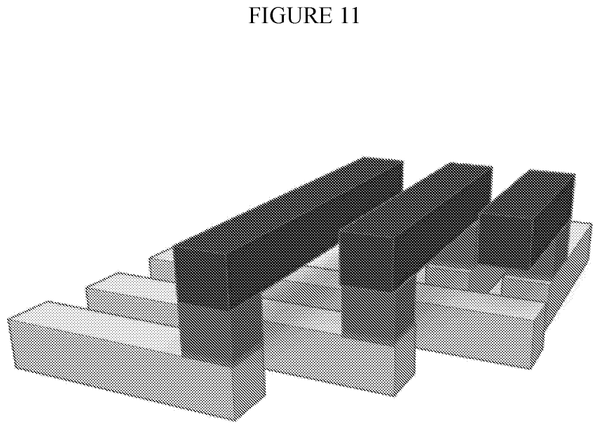

FIG. 11 is a simplified cross-sectional view of various tracks for transformer devices according to an example of the present invention. As shown, tracks can be naturally broken up or separated by isolation regions into segments by removing a via at a crossing region. That is, one of the segments is insulated from an underlying segment with isolation material. In an example, tracks can be broken up or separated into segments by simply cutting the track in a portion of the metal regions.

In an example, the present invention provides a method of fabricating a distributed transformer device. The method includes providing a semiconductor substrate member comprising a first surface and a second surface. The method includes forming a first insulting material overlying the second surface and forming a plurality of contact regions configured within the insulating material. The method includes forming a first metal material having a thickness and configured spatially in a first pattern. The first pattern has a plurality of primary tracks numbered from 2 to J, where J is an integer from two to forty, each of the primary tracks having a first end and a second end, and a plurality of secondary tracks numbered from 2 to K, where K is an integer from two to forty.

In an example, the method includes forming a second insulating material overlying the first metal material. The method includes forming one or more via structures in the second insulating material to connect to one or more portions of at least one of the plurality of primary tracks and at least one or more portions of the secondary tracks. In an example, the method includes forming a second metal material configured spatially in a second pattern overlying the one or more via structures. The second metal material electrically connects at least one of the primary tracks such that a rhombus shape is formed when viewed from a top-view of the plurality of primary tracks, the plurality of secondary tracks, and the second metal material that has been spatially patterned. A distributed transformer device is formed from the plurality of primary tracks, the plurality of secondary tracks, and the second metal material.

In an example, the present distributed transformer device is manufacturing using a semiconductor manufacturing process. Such process involves a series of steps that include etching, deposition or sputtering, plating, polishing, lithography, and other techniques. Further details of such process can be found throughout the present specification and more particularly below.

In an example, the process begins with a silicon wafer as the substrate. In an example, the substrate's properties, such as conductivity and doping, are adjusted to suit the requirements of the transformer. In an example, etching involves selectively removing material from the substrate to create patterns. Reactive ion etching (RIE) or wet chemical etching can be used to define the transformer's primary and secondary coils, as well as the insulating layers between them. Etching is guided by a photomask, which defines the desired pattern on the substrate. In an example, after etching, insulating, and conducting layers are deposited onto the substrate using techniques like chemical vapor deposition (CVD) or metal sputtering. These layers form the transformer's tracks, primary and secondary tracks, and insulating layers as shown.

In an example, photolithography defines the patterns for the conducting and insulating layers. A photoresist is applied to the substrate, exposed to UV light through a photomask, and then developed to create a mask for subsequent etching or deposition steps. In an example, insulating layers, such as silicon dioxide (SiO2) or silicon nitride (Si3N4), are deposited over the substrate to provide electrical insulation between and among the primary and secondary tracks. In an example, metal conductors, often copper or aluminum, are deposited onto the substrate to form the primary and secondary tracks of the transformer. These conductors may be patterned using photolithography and etching to achieve the desired coil geometries. In an example, electroplating can be employed to thicken and enhance the conductivity of the transformer tracks. This step can improve the transformer's performance. In an example, additional insulating layers may be deposited or grown over the conductors to provide further isolation and prevent short circuits. In an example, a passivation layer, usually an insulating material like silicon dioxide or silicon nitride, is deposited to protect the device from environmental factors and contaminants.

After the transformer device is fabricated on the wafer, individual devices are separated through dicing. They are then bonded to a package and connected to external pins or pads for interfacing with other circuitry.

In an example, the specific techniques and materials used may vary depending on the desired transformer specifications, the semiconductor process technology, and the application.

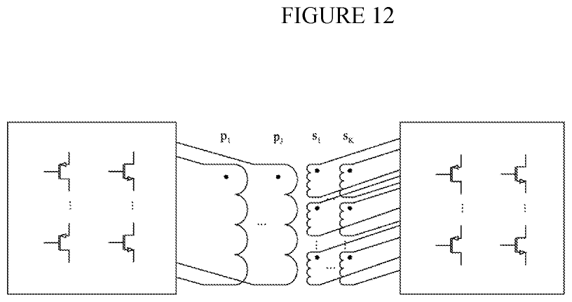

FIG. 12 is a simplified diagram of an integrated CMOS device coupled to a distributed transformer device according to an example of the present invention. As shown, the CMOS device is coupled to primary tracks P1, P2. The secondary tracks SI to SK are coupled to CMOS device as shown. As shown, the transformer connects to a plurality of distributed CMOS cells. Each endpoint of each segment of each track connects to an nMOS or pMOS transistor gate region, a source region, or a drain region.

In an example, the CMOS semiconductor integrated circuit is a type of semiconductor device that utilizes CMOS technology for its construction. CMOS technology is desirable for low power consumption, high noise immunity, and compatibility with high-density integration. In an example, the CMOS IC is built using a combination of p-type and n-type metal-oxide-semiconductor field-effect transistors (MOSFETs) on a silicon substrate. The MOSFETs in CMOS technology includes a pair of complementary transistors, namely, a pMOS (p-channel MOSFET) and an nMOS (n-channel MOSFET). These transistors are arranged in a complementary configuration, where one conducts when the other is off, and vice versa.

In an example, the CMOS ICs primarily includes logic gates, such as NAND gates, NOR gates, AND gates, and XOR gates, which are constructed using the complementary pairs of pMOS and nMOS transistors. These logic gates perform digital operations and form the building blocks for more complex digital circuits.

In an example, the operation of a CMOS IC is based on the principle that when the voltage applied to the gate terminal of a MOSFET exceeds a certain threshold voltage, it allows current to flow between the source and drain terminals. In a pMOS transistor, a positive voltage turns it off (0 logic level), while a negative voltage turns it on (1 logic level). Conversely, in an nMOS transistor, a positive voltage turns it on (1 logic level), while a negative voltage turns it off (0 logic level). Various applications can be used with the present CMOS IC and distributed transformer.

A CMOS integrated circuit (IC) chip is a fundamental component in electronics. The CMOS IC chip is type of semiconductor device that combines various electronic components, such as transistors, resistors, capacitors, and interconnects, on a single silicon substrate. CMOS technology is widely used in analog circuits, rf circuits, digital logic circuits, memory chips, microprocessors, and various other applications due to its low power consumption, high integration density, and relatively low manufacturing costs.

In an example, a CMOS integrated circuit chip is formed on a substrate. The chip is typically made from a silicon wafer, which serves as the foundation for all the components. Silicon is a semiconductor material with the ability to conduct electricity under certain conditions.

In an example, the CMOS chip includes metal-oxide-semiconductor field-effect transistors (MOSFETs). These transistors come in two types: n-channel (NMOS) and p-channel (PMOS). They work in tandem to create digital logic circuits. When combined, NMOS and PMOS transistors form complementary pairs, which is where the term “Complementary” in CMOS comes from.

Examples of the CMOS chip includes logic gates, inverters, amplifiers, interconnects, clocking and timing circuits, memory cells, analog components, power and ground, among others. In an example, logic gates like AND, OR, NOT, and XOR are formed by interconnecting these transistors. These gates process binary signals (0s and 1s) and form the basis of digital circuitry. CMOS logic gates are characterized by their low power consumption when switching between states. In an example, inverters are fundamental building blocks that include a PMOS and an NMOS transistor connected in series. They perform the operation of logical NOT and are used extensively in circuit design. In an example, copper or aluminum interconnects are used to establish connections between transistors, resistors, and other components on the chip. These interconnects create the complex circuitry needed for various functions.

In an example, CMOS chips often incorporate clocking and timing circuits to synchronize the operations of different parts of the chip. These circuits ensure that the logic gates switch at the right time, avoiding data corruption and errors. In an example, CMOS chips can include memory cells for temporary storage of data. Static RAM (SRAM) and dynamic RAM (DRAM) cells are common types of memory cells used in integrated circuits. In an example, CMOS technology is not only used for digital logic but also for analog circuitry. Components like operational amplifiers, analog-to-digital converters, and digital-to-analog converters can be integrated onto the chip. In an example, power and ground distribution networks provide the necessary supply voltage and reference potential to different parts of the chip.

In a preferred example, the plurality of primary tracks and the plurality of secondary tracks are configured to form the transformer device such that a parasitic electromagnetic field from the transformer device is free from a detrimental influence to any devices configured from the plurality of CMOS cells. That is, the transformer device is configured to reduce and/or minimize any detrimental influence to any circuits configured by the CMOS cells.

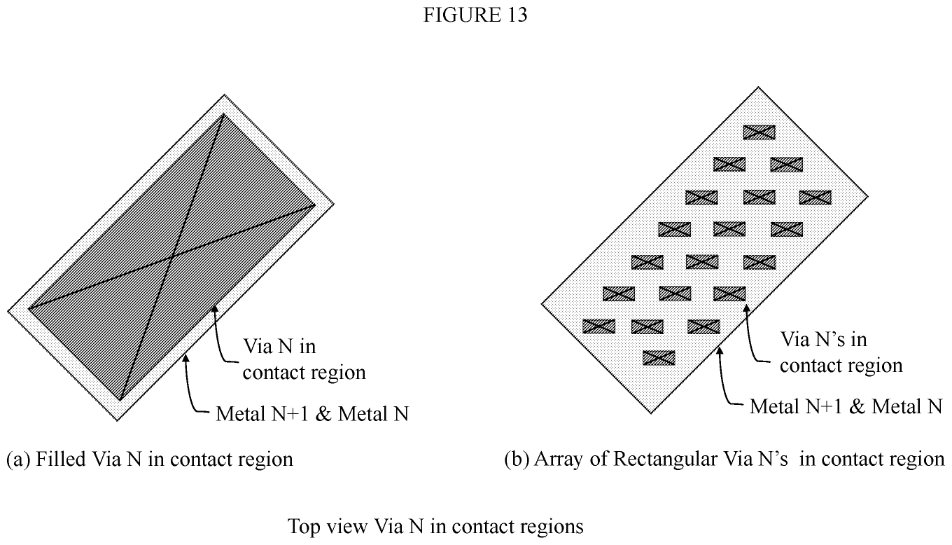

FIG. 13 is a simplified diagram of a contact structure according to an example of the present invention. As shown, the diagram has a contact structure including a lower metal layer and an upper metal layer. The metal layer is interconnected using a via structure which occupies a large region of the contact structure. Alternatively, the contact structure comprises a plurality of via structures arranged in a pattern to occupy from about 10% to 50% of an area of the contact structure. In an example, the pattern can be arbitrary or arranged in an array or other organized manner. The plurality of via structures reduces contact resistance between an upper and lower metal interconnect.

In an example, the present invention provides a transformer device. In an example, the transformer device has a semiconductor substrate member comprising a first surface and a second surface. In an example, the semiconductor substrate can be a silicon wafer, a silicon on insulator wafer, a compound semiconductor material, such as any II/VI or III/V material, among others. In an example, the device has an insulting material overlying the second surface. In an example, a plurality of contact regions are configured within the insulating material. In an example, the device has a metal material having a thickness and configured spatially in a pattern to form a distributed transformer device. The pattern has a plurality of primary tracks numbered from 2 to J, where J is an integer from two to forty, and a plurality of secondary tracks numbered from 2 to K, where K is an integer from two to forty. In an example, the plurality of primary tracks and the plurality of secondary tracks are configured collectively to form an electromagnetic field from the plurality of primary tracks to produce a magnetic flux to induce a varying current coupled to the plurality of secondary tracks.

In an example, the present invention provides an alternative transformer device. The device has a semiconductor substrate member comprising a first surface and a second surface. In an example, the device has a plurality of CMOS cells configured overlying a first portion of the second surface. In an example, an insulting material is overlying a second portion of the second surface. In an example, a plurality of contact regions configured within the insulating material such that each of the contact regions comprises a via structure. In an example, the device has a metal material having a thickness and configured spatially in a pattern to form a transformer device. In an example, the pattern has a plurality of primary tracks numbered from 2 to J, where J is an integer from two to forty. Each of the primary tracks has a first end point and a second end point, and a length defined between the first end point the second end point. In an example, the pattern has a plurality of secondary tracks numbered from 2 to K, where K is an integer from two to forty. Each of the secondary tracks has a first end point and a second end point, and a length defined between the first end point and the second end point. In an example, the plurality of primary tracks and the plurality of secondary tracks are configured collectively to form an electromagnetic field from the plurality of primary tracks to produce a magnetic flux to induce a varying current coupled to the plurality of secondary tracks.

In an example, any one of the tracks in the pattern can induce a varying current in any one of the tracks.

In an example, each of the plurality of primary tracks is electrically isolated from any one of the plurality of primary tracks. In an example, each of the plurality of primary tracks is an electrically isolated net. In an example, each of the plurality of secondary tracks is an electrically isolated net. In an example, each of the plurality of primary tracks comprises a first end point and a second point. In an example, each of the plurality of secondary tracks comprises a first end point and a second point.

In an example, the plurality of primary tracks and the plurality of secondary tracks are configured in a rhombus shape within a single planar region or thickness of material. In an example, the plurality of primary tracks and the plurality of secondary are configured in N rhombus shapes, where N is 2 and greater.

In an example, the plurality of contact regions are configured at a crossing region coupled to the plurality of primary tracks and the plurality of secondary tracks.

In an example, the metal material comprises a copper material, among others. In an example,

the semiconductor substrate comprises a plurality of CMOS cells. In an example, the CMOS cells are configured by a suitable design rule such as 1 micron, 0.5 micron, and other submicron dimensions, including 80 nm, 40 nm, and others.

In an example, the plurality of primary tracks are generally arranged such that at least a first group is parallel to a second group. In an example, the plurality of secondary tracks are arranged such that at least a first group is parallel to a second group.

In an example, the plurality of primary tracks are configured within a planar region or a thickness of a planar region.

In an example, each of the primary tracks has a width ranging from half a thickness of a metal to ten times a thickness of a metal comprising a copper material. Other thicknesses can also be used. In an example, each of the secondary tracks has a width ranging from half to five times a thickness. Other thicknesses for the secondary tracks can be used. In an example, each of the primary tracks has a thickness of one micron to three microns.

In an example, the invention provides a transformer device. The transformer device has a semiconductor substrate member comprising a first surface and a second surface. The device has an insulting material overlying the second surface. The device has a plurality of contact regions configured within the insulating material. The device has a first metal material from a first metal layer having a thickness and configured spatially in a first pattern and a second metal material from a second metal layer having a thickness and configured spatially in a second pattern. In an example, the device has a plurality of primary tracks numbered from 2 to J, where J is an integer from two to forty and a plurality of secondary tracks numbered from 2 to K, where K is an integer from two to forty. In an example, the device has a plurality of segments characterizing each of the plurality of secondary tracks numbered from 2 to L, where L is an integer greater than 2. Each of the plurality of segments having a first end and a second end. In an example, the plurality of primary tracks and the plurality of secondary tracks are configured collectively to form an electromagnetic field from the plurality of primary tracks to produce a magnetic flux to induce a varying current coupled to the plurality of secondary tracks.

In an example, each of the plurality of segments is electrically isolated from any one of the plurality of segments; and at most one of the plurality of primary tracks is composed of only the first metal material. In an example, at least one or more of the plurality of segments is configured on a straight line or is configured on a line having a 90 Degree angle. In an example, each of the first ends of the plurality of segments is connected to a common first node and wherein each of the second ends of the plurality of segments is connected to a common first node. In an example, each of the plurality of segments in one of the plurality of secondary tracks are coupled to form a continuous track.

In an example, each of the plurality of primary tracks is electrically isolated from any one of the plurality of primary tracks. In an example, each of the plurality of primary tracks is an electrically isolated net. In an example, each of the plurality of secondary tracks is an electrically isolated net. In an example, each of the plurality of primary tracks comprises a first end point and a second point. In an example, each of the plurality of secondary tracks comprises a first end point and a second point. In an example, the plurality of primary tracks and the plurality of secondary tracks are configured in a rhombus shape within a single planar region or a thickness of material. In an example, the plurality of primary tracks and the plurality of secondary are configured in N rhombus shapes, where N is 2 and greater. In an example, the plurality of contact regions are configured at a crossing region coupled to the plurality of primary tracks and the plurality of secondary tracks.

In an example, the first metal material comprises a copper material. In an example, the semiconductor substrate comprises a plurality of CMOS cells. In an example, the plurality of primary tracks are arranged such that at least a first group is parallel to a second group. In an example, the plurality of secondary tracks are arranged such that at least a first group is parallel to a second group. In an example, the plurality of primary tracks are configured within a planar region. In an example, each of the primary tracks has a width ranging from half a thickness of a metal to ten times a thickness of a metal comprising a copper material. In an example, each of the secondary tracks has a width ranging from half to five times a thickness. In an example, the primary tracks has a thickness of one micron to three microns.

Although the above has been described in specific shapes and structures, the invention can have variations. That is, the shape can be varied in shape, curved, or formed in other shapes to achieve the invention as described in the claims.

In other examples, each of the tracks has been described in terms of a constant width, however, each of the tracks can be patterned or shaped in different ways according to alternative examples.

While the above is a full description of the specific examples, various modifications, alternative constructions and equivalents may be used. As an example, the distributed transformer device can include any combination of elements described above, as well as outside of the present specification. In an example, the distributed transformer has been described in terms of a generalized configuration but can include multiple tracks, 1, 2, 3, 4 . . . Nth, and multiple segments, 1, 2, 3, 4 . . . Mth. Other configurations can also exist depending upon the application. Therefore, the above description and illustrations should not be taken as limiting the scope of the present invention which is defined by the appended claims.

1-34. (canceled)

35. A method of fabricating a distributed transformer device, the method comprising:
providing a semiconductor substrate member comprising a first surface and a second surface;
forming a first insulting material overlying the second surface;
forming a plurality of contact regions configured within the insulating material;
forming a first metal material having a thickness and configured spatially in a pattern, the pattern comprising:
a plurality of primary tracks numbered from 2 to J, where J is an integer from two to forty, each of the primary tracks having a first end and a second end;
a plurality of secondary tracks numbered from 2 to K, where K is an integer from two to forty, each of the plurality of secondary tracks comprises a plurality of segments, each of the segments having a first end and a second end;
forming a second insulating material overlying the first metal material;
forming one or more via structures in the second insulating material to connect to one or more portions of at least one of the plurality of primary tracks and at least one or more portions of the secondary tracks; and
forming a second metal material configured spatially in a pattern overlying the one or more via structures to electrically connect at least one of the primary tracks such that a rhombus shape is formed when viewed from a top-view of the plurality of primary tracks, the plurality of secondary tracks, and the second metal material that has been spatially patterned.

36-52. (canceled)

53. An integrated circuit device comprising:
a semiconductor substrate member comprising a first surface and a second surface;
an insulting material overlying the second surface;
a first metal material formed in a first layer overlying the insulating material, the first metal material having a first thickness and configured spatially in a first pattern;
a second metal material formed in a second layer overlying the first metal material having a second thickness and configured spatially in a second pattern;
a plurality of rhombus shaped tracks numbered from 4 to N, where N is an integer from 4 to 80, configured from the first pattern and the second pattern, the plurality of rhombus shaped tracks configured in a shifted arrangement such that a second rhombus shaped track is placed adjacent to a first rhombus shaped track, a third rhombus shaped track is placed adjacent to the second rhombus shaped track, and the Nth rhombus shaped track is placed adjacent to an N−1 rhombus shaped track such that each pair of lateral corners opposed to each other for each rhombus shaped track is arranged along a first lateral imaginary line, a first vertical corner for each rhombus shaped track is arranged along a second lateral imaginary line in parallel with the first lateral imaginary line, and a second vertical corner for each rhombus shaped track is arranged along a third lateral imaginary line in parallel to the first lateral imaginary line; and
a transformer device configured from a plurality of primary tracks comprising at least a first pair of the rhombus shaped tracks; and a plurality of secondary tracks comprising at least a second pair of the rhombus shaped tracks, each of the second pair of rhombus shaped tracks comprising at least two segments, such that the plurality of primary tracks forms an electromagnetic field and resulting magnetic flux to induct a varying current coupled to one or more of the plurality of secondary tracks.

54. The device of claim 53 wherein the plurality of rhombus shaped tracks are configured such that each rhombus shaped track is shifted by a gap to an adjacent rhombus shaped track; at least N−1 of the plurality of rhombus shaped tracks comprises a contact structure, the contact structure comprising a plurality of via structures arranged in a pattern to occupy from about 10% to 50% of an area of the contact structure, the pattern being arbitrary or arranged.

55. The device of claim 53 wherein each of the plurality of rhombus shaped tracks is isolated from any other one of the plurality of rhombus shaped tracks.

56. The device of claim 53 wherein each of the N−1 of the plurality of rhombus shaped tracks is configured with a gap to be isolated from at least one or more of the plurality of rhombus shaped tracks.

57. The device of claim 53 wherein each of the N−1 of the plurality of rhombus shaped tracks is configured with a gap to be isolated from at least one or more of the plurality of rhombus shaped tracks, each gap is an open region in the rhombus shaped track.

58. The device of claim 53 wherein each of the N−1 of the plurality of rhombus shaped tracks is configured with a gap to be isolated from at least one or more of the plurality of rhombus shaped tracks, each gap is an open region in a portion of the metal material in the rhombus shaped track; and further comprising an interconnect connecting the open region on an overlying metal material using at least a pair of via structures.

59. The device of claim 53 wherein a pair of primary tracks are arranged adjacent to each other and are spatially disposed between at least a pair of secondary tracks, each of the primary tracks being electrically isolated from the other primary track and each pair of the primary tracks are electrically coupled through at least one electrical device.

60. A transformer device comprising:
a semiconductor substrate member comprising a first surface and a second surface;
an insulting material overlying the second surface;
a plurality of contact regions configured within the insulating material;
a first metal material from a first metal layer having a thickness and configured spatially in a first pattern and a second metal material from a second metal layer having a thickness and configured spatially in a second pattern, the first pattern and the second pattern comprising:
a plurality of primary tracks numbered from 2 to J, where J is an integer from two to forty;
a plurality of secondary tracks numbered from 2 to K, where K is an integer from two to forty;
a plurality of segments characterizing each of the plurality of secondary tracks numbered from 2 to L, where L is an integer of 3 and greater, each of the plurality of segments having a first end and a second end;
whereupon the plurality of primary tracks and the plurality of secondary tracks are configured collectively to form an electromagnetic field from the plurality of primary tracks to produce a magnetic flux to induce a varying current coupled to the plurality of secondary tracks.

61. The device of claim 60 wherein each of the plurality of segments is electrically isolated from any one of the plurality of segments; and wherein at most one of the plurality of primary tracks is composed of only the first metal material.

62. The device of claim 60 wherein at least one or more of the plurality of segments is configured on a straight line or is configured on a line having a 90 Degree angle.

63. The device of claim 60 wherein each of the first ends of the plurality of segments is connected to a common first node and wherein each of the second ends of the plurality of segments is connected to a common first node.

64. The device of claim 60 wherein each of the plurality of segments in one of the plurality of secondary tracks are coupled to form a continuous track.

65. The device of claim 60 wherein each of the plurality of primary tracks is electrically isolated from any one of the plurality of primary tracks.

66. The device of claim 60 wherein each of the plurality of primary tracks is an electrically isolated net.

67. The device of claim 60 wherein each of the plurality of secondary tracks is an electrically isolated net.

68. The device of claim 60 wherein each of the plurality of primary tracks comprises a first end point and a second point.

69. The device of claim 60 wherein each of the plurality of secondary tracks comprises a first end point and a second point.

70. The device of claim 60 wherein the plurality of primary tracks and the plurality of secondary tracks are configured in a rhombus shape within a single planar region or a thickness of material.

71. The device of claim 60 wherein the plurality of primary tracks and the plurality of secondary are configured in N rhombus shapes, where N is 2 and greater.

72. The device of claim 60 wherein the plurality of contact regions are configured at a crossing region coupled to the plurality of primary tracks and the plurality of secondary tracks.

73. The device of claim 60 wherein the first metal material comprises a copper material.

74. The device of claim 60 wherein the semiconductor substrate comprises a plurality of CMOS cells.

75. The device of claim 60 wherein the plurality of primary tracks are arranged such that at least a first group is parallel to a second group.

76. The device of claim 60 wherein the plurality of secondary tracks are arranged such that at least a first group is parallel to a second group.

77. The device of claim 60 wherein the plurality of primary tracks are configured within a planar region.

78. The device of claim 60 wherein each of the primary tracks has a width ranging from half a thickness of a metal to ten times a thickness of a metal comprising a copper material.

79. The device of claim 60 wherein each of the secondary tracks has a width ranging from half to five times a thickness.

80. The device of claim 60 wherein the primary tracks has a thickness of one micron to three microns.
